(19) United States
(12) Patent Application Publication
(10) Pub. No.: US 2022/0139599 A1
(43) Pub. Date: May 5, 2022

(54) METHOD FOR MANUFACTURING THERMISTOR, AND THERMISTOR

(71) Applicant: MITSUBISHI MATERIALS CORPORATION, Tokyo (JP)

(72) Inventors: Takehiro Yonezawa, Naka-shi (JP); Satoko Higano, Naka-shi (JP)

(73) Assignee: MITSUBISHI MATERIALS CORPORATION, Tokyo (JP)

(21) Appl. No.: 17/429,080

(22) PCT Filed: Feb. 5, 2020
(86) PCT No.: PCT/JP2020/004213

§ 371 Date: Aug. 6, 2021

(30) Foreign Application Priority Data
Feb. 15, 2019 (JP) 2019-025313

(51) Int. Cl. H01C 17/28; H01C 1/14; H01C 7/00; C23C 14/10; C23C 14/34; C25D 17/20; C25D 3/12; C25D 3/30; B41M 1/12; B41M 3/00

(52) U.S. Cl. CPC H01C 17/281; H01C 1/14; H01C 7/008; C23C 14/10; B41M 3/006; C25D 17/20; C25D 3/12; C25D 3/30; B41M 1/12; C23C 14/34

(57) ABSTRACT

The present invention is provided with a base electrode layer forming step of forming a base electrode layer by applying and sintering a conductive paste on an end surface of the thermistor element, an oxide layer forming step of forming an oxide layer on a surface of the base electrode layer, a cover electrode layer forming step of forming a cover electrode layer by applying and sintering a conductive paste on a surface of the oxide layer, and a conduction heat treatment step of performing a heat treatment such that the base electrode layer and the cover electrode layer are electrically conductive, in which the electrode portion having the base electrode layer and the cover electrode layer is formed and a plating step of forming a metal plating layer on a surface of the cover electrode layer is provided after the conduction heat treatment step.

### TECHNICAL FIELD

This invention relates to a method for manufacturing a thermistor, which includes a thermistor element and an electrode portion formed on an end surface of the thermistor element, and to a thermistor.

Priority is claimed on Japanese Patent Application No. 2019-025313, filed in Japan on Feb. 15, 2019, the content of which is incorporated herein by reference.

### BACKGROUND ART

The thermistor described above has a characteristic by which the electrical resistance thereof changes according to the temperature and is applied in the temperature compensation of various electronic devices, in temperature sensors, and the like. In particular, recently, chip-type thermistors mounted on circuit boards have been widely used.

The thermistor described above has a structure formed of a thermistor element and a pair of electrode portions at both ends of the thermistor element.

The thermistor element has properties of being weak against acids and alkalis and being easily reduced. When the composition thereof changes, there is a concern that the characteristics thereof may change. For this reason, for example, as shown in Patent Document 1, a technique for forming a protective film on the surface of the thermistor element was proposed. There is a demand for the protective film to have resistance to a plating solution, environmental resistance, insulation, and the like, in order to suppress deterioration of the thermistor element during subsequent steps and use.

Here, in Patent Document 1, a protective film formed of thick glass is formed by sintering a glass paste applied to the surface of the thermistor element.

In addition, since electrode portions are formed on both ends of the thermistor element, a protective film is not formed on the end surfaces of the thermistor where the electrode portions are formed. Here, the electrode portions are formed by, for example, sintering a conductive paste including conductive materials such as Ag applied to both ends of the thermistor element. In addition, a Ni plating layer or a Sn plating layer is formed on the surfaces of the electrode portions formed of the sintered material.

### CITATION LIST

### Patent Document

[Patent Document 1]

Japanese Unexamined Patent Application, First Publication No. H03-250603

### SUMMARY OF INVENTION

### Technical Problem

As shown in Patent Document 1, in a case where electrode portions formed of a conductive paste sintered material are formed on the end surfaces of a thermistor element, uneven application of the conductive paste or contamination of foreign matter in the conductive paste may produce pores in the electrode portions and create a porous structure. in a case where a plating layer is formed on such an electrode portion, there were concerns that the plating solution may penetrate into the electrode portion and that the thermistor element and the plating solution may come into contact to cause deterioration of the thermistor element. In addition, there were concerns that the plating metal may precipitate at the interface between the thermistor element and the electrode portions and that the resistance value may change significantly before and after plating.

This invention was made in view of the circumstances described above and has an object of providing a method for manufacturing a thermistor which is able to manufacture a thermistor with which, even in a case where a plating layer is formed on a surface of an electrode portion, it is possible to suppress the penetration of a plating solution inside the electrode portion and in which a thermistor element has stable characteristics, as well as a thermistor having stable characteristics which is manufactured by this method for manufacturing a thermistor.

### Solution to Problem

In order to solve the problem described above, the method for manufacturing a thermistor of the present invention is a method for manufacturing a thermistor which includes a thermistor element and an electrode portion formed on an end surface of the thermistor element, the method including a base electrode layer forming step of forming a base electrode layer by applying and sintering a conductive paste (may be referred to below as a “first conductive paste”) on an end surface of the thermistor element, an oxide layer forming step of forming an oxide layer on a surface of the base electrode layer, a cover electrode layer forming step of forming a cover electrode layer by applying and sintering a conductive paste (may be referred to below as a “second conductive paste”) on a surface of the oxide layer, and a conduction heat treatment step of performing a heat treatment such that the base electrode layer and the cover electrode layer are electrically conductive, in which the electrode portion having the base electrode layer and the cover electrode layer is formed and a plating step of forming a metal plating layer on a surface of the cover electrode layer is provided after the conduction heat treatment step.

According to the method for manufacturing a thermistor of the present invention, as described above, since the electrode portion is formed by the base electrode layer forming step, the oxide layer forming step, the cover electrode layer forming step, and the conduction heat treatment step, the electrode portion has a two-layer structure of the base electrode layer and the cover electrode layer, the pores in the base electrode layer and the pores in the cover electrode layer do not conununicate and, in the plating step, the penetration of the plating solution at the interface between the cover electrode layer and the base electrode layer is prevented and it is possible to suppress contact between the thermistor element and the plating solution. In addition, it is possible to suppress precipitation of the plating metal at the interface between the thermistor element and the electrode portion.

In addition, since there is provided a conduction heat treatment step in which a heat treatment is performed such that the base electrode layer and the cover electrode layer are electrically conductive, even if an oxide layer is formed between the base electrode layer and the cover electrode layer, it is possible to make the base electrode layer and the cover electrode layer electrically conductive and to secure the characteristics of the electrode portion. The oxide layer formed in the oxide layer forming step may remain at the interface between the base electrode layer and the cover electrode layer or may disappear completely in the conduction heat treatment step, as long as the conduction between the base electrode layer and the cover electrode layer is sufficient.

Here, in the method for manufacturing a thermistor of the present invention, the base electrode layer forming step may be configured to form the base electrode layer by applying and sintering a glass-filled metal paste containing metal powder and glass powder. That is, in the method for manufacturing a thermistor of the present invention, the first conductive paste may be formed to be a glass-filled metal paste containing metal powder and glass powder.

In this case, since the base electrode layer is formed by sintering the glass-filled metal paste as the first paste, it is possible to improve the adhesion between the thermistor element and the base electrode layer.

In addition, in the method for manufacturing a thermistor of the present invention, the cover electrode layer forming step may be configured to form the cover electrode layer by applying and sintering a glass-filled metal paste containing metal powder and glass powder. That is, in the method for manufacturing a thermistor of the present invention, the second conductive paste may be formed to be a glass-filled metal paste containing metal powder and glass powder.

In this case, since the cover electrode layer is formed by sintering the glass-filled metal paste as the second conductive paste, in the conduction heat treatment step, it is possible to efficiently eliminate at least a part of the oxide layer through a reaction between the glass and the oxide layer and to achieve sufficient conduction between the base electrode layer and the cover electrode layer.

Furthermore, in the method for manufacturing a thermistor of the present invention, the oxide layer is preferably formed of a silicon oxide.

In this case, since the oxide layer is formed of a silicon oxide, the environmental resistance is excellent, it is possible to reliably form the cover electrode layer on the surface of this oxide layer, and it is possible to stably form an electrode portion having a two-layer structure of the base electrode layer and the cover electrode layer.

The thermistor of the present invention is provided with a thermistor element and an electrode portion formed on an end surface of the thermistor element, in which the electrode portion is provided with a base electrode layer formed on an end surface of the thermistor element and a cover electrode layer laminated on the base electrode layer, and a metal plating layer is formed on a surface of the electrode portion, and a penetration depth of a plating metal forming the metal plating layer into the electrode portion is less than a thickness of the electrode portion.

According to the thermistor of this structure, since the electrode portion has a two-layer structure formed of a base electrode layer and a cover electrode layer and a penetration depth of the plating metal forming the metal plating layer into the electrode portion is less than the thickness of the electrode portion, contact between the plating solution and the thermistor element during plating is suppressed. In addition, precipitation of the plating metal on the interface between the thermistor element and the electrode portion is also suppressed. Thus, it is possible to provide a thermistor having various stable characteristics.

### Advantageous Effects of Invention

According to the present invention, it is possible to provide a method for manufacturing a thermistor which is able to manufacture a thermistor with which, even in a case where a plating layer is formed on a surface of an electrode portion, it is possible to suppress the penetration of a plating solution inside the electrode portion and in which a thermistor element has stable characteristics, as well as a thermistor having stable characteristics which is manufactured by this method for manufacturing a thermistor.

### BRIEF DESCRIPTION OF DRAWINGS

FIG. 1 is a schematic cross-sectional explanatory diagram of a thermistor according to the present embodiment.

FIG. 2 is an enlarged explanatory diagram of the vicinity of an electrode portion of the thermistor according to the present embodiment.

FIG. 3 is a flow diagram showing a method for manufacturing a thermistor according to the present embodiment.

FIG. 4 is an observation photograph of the electrode portion of a thermistor in Invention Example 1 in the Examples.

FIG. 5 is an observation photograph of the electrode portion of a thermistor in Comparative Example 1 in the Examples.

### Description of Embodiments

A description will be given below of embodiments of the present invention with reference to the attached drawings. Here, each of the embodiments shown below are specifically described in order to better understand the gist of the invention and do not limit the present invention unless otherwise specified. In addition, in the drawings used in the following description, in order to make the characteristics of the present invention easy to understand, for convenience, the main parts may be shown after being enlarged and the dimensional ratios of the respective components may not always be the same as in practice.

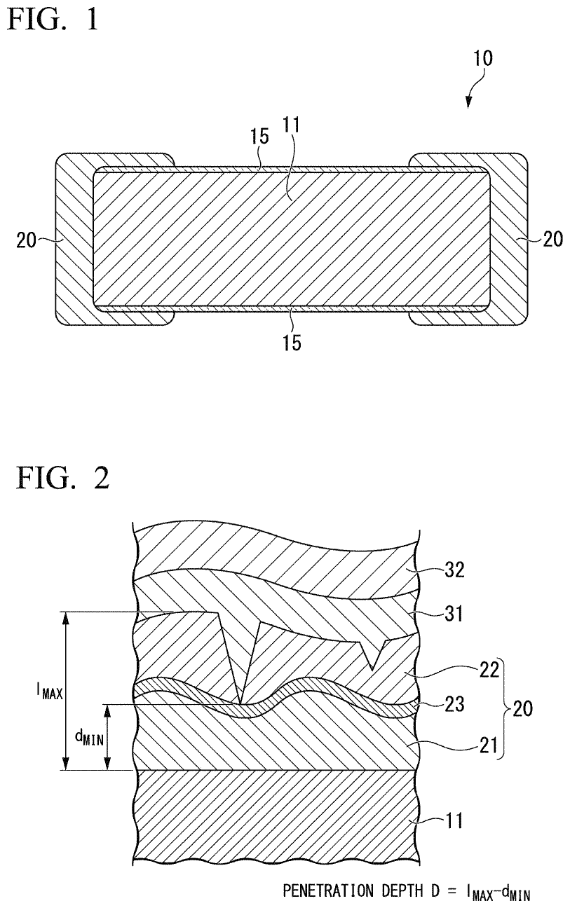

As shown in FIG. 1, a thermistor 10 according to the present embodiment has a prismatic shape, for example, and is provided with a thermistor element 11, a protective film 15 formed on the surface of the thermistor element 11, and electrode portions 20 formed on each of both end portions of the thermistor element 11.

Here, as shown in FIG. 1, the protective film 15 is not formed on both end surfaces of the thermistor element 11 and the electrode portions 20 are formed to be in direct contact with the thermistor element 11.

The thermistor element 11 has a characteristic by which the electrical resistance changes according to the temperature. The thermistor element 11 has a low resistance to acids and alkalis and there is a concern that the composition may change due to a reduction reaction or the like and that the characteristics thereof may change significantly. Thus, in the present embodiment, the protective film 15 for protecting the thermistor element 11 is formed.

Here, there is a demand for the protective film 15 to have resistance to a plating solution, environmental resistance, and insulation. Therefore, in the present embodiment, the protective film 15 may be formed of a silicon oxide, specifically, SiO₂.

In addition, in the present embodiment, to suppress discontinuity in the film, the thickness of the protective film 15 is preferably 100 nm or more, and more preferably 300 nm or more. On the other hand, it is possible to arbitrarily set the upper limit of the thickness of the protective film 15 by selecting an appropriate protective film forming method; however, 3000 nm or less is preferable.

As shown in FIG. 2, the electrode portion 20 has a two-layer structure provided with a base electrode layer 21 formed on an end surface of the thermistor element 11 and a cover electrode layer 22 laminated and arranged on the base electrode layer 21.

The base electrode layer 21 is formed by sintering a conductive paste (first conductive paste), as described below, and, in the present embodiment, may be formed of a sintered material of Ag. In this case, pores will be present inside the base electrode layer 21.

In addition, the cover electrode layer 22 is also formed by sintering a conductive paste (second conductive paste), as described below, and, in the present embodiment, may be formed of a sintered material of Ag. In this case, pores will also be present inside the cover electrode layer 22.

A thickness t1 of the base electrode layer 21 is preferably in a range of 2 μm or more and 20 μm or less.

By setting the thickness ti of the base electrode layer 21 to 2 μm or more, the amount of glass is secured and erosion of the protective film 15 occurs at a suitable level. In addition, to ensure erosion of the protective film 15, it is not necessary to increase the amount of glass more than necessary and it is possible to suppress an increase in the resistance value through the percolation of conductive particles. On the other hand, it is possible to suppress loss of material by setting the thickness t1 of the base electrode layer 21 to 20 μm or less.

The lower limit of the thickness t1 of the base electrode layer 21 is preferably 3 μm or more, and more preferably 5μm or more. On the other hand, the upper limit of the thickness t1 of the base electrode layer 21 is preferably 15 μm or less, and more preferably 10 μm or less.

In addition, a thickness t2 of the cover electrode layer 22 is preferably in a range of 3 μm or more and 20 μm or less.

By setting the thickness t2 of the cover electrode layer 22 to 3 μm or more, the amount of glass is secured and erosion of the protective film 15 occurs at a suitable level. In addition, to ensure erosion of the protective film 15, it is not necessary to increase the amount of glass more than necessary and it is possible to suppress an increase in the resistance value through the percolation of conductive particles. On the other hand, by setting the thickness t2 of the cover electrode layer 22 to 20 μm or less, it is possible to suppress the loss of material and to suppress the element shape from swelling significantly only at the electrode portions.

The lower limit of the thickness t2 of the cover electrode layer 22 is preferably 4 μm or more, and more preferably 5 μm or more. On the other hand, the upper limit of the thickness t2 of the cover electrode layer 22 is preferably 15 μm or less, and more preferably 10 μm or less.

In addition, a Ni plating layer 31 is formed on the surface of the electrode portion 20 and a Sn plating layer 32 is formed so as to be laminated on the Ni plating layer 31.

In the present embodiment, a penetration depth D of the Ni of the Ni plating layer 31 into the electrode portion 20 is set to be less than a thickness t of the electrode portion 20. In other words, the Ni of the Ni plating layer 31 does not reach the bonding interface between the thermistor element 11 and the electrode portion 20 (the base electrode layer 21).

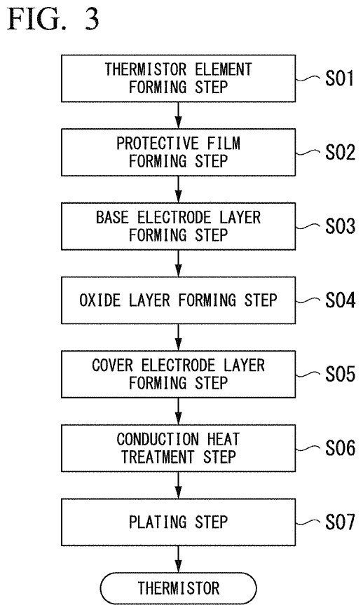

Next, a description will be given of a method for manufacturing the thermistor 10, which is the present embodiment described above, using the flow diagram in FIG. 3.

### (Thermistor Element Forming Step S01)

First, the thermistor element 11 forming a prismatic shape is manufactured. In the present embodiment, the thermistor element 11 described above is manufactured by cutting a plate material formed of a thermistor material into strip shapes.

### (Protective Film Forming Step S02)

Next, the protective film 15 is formed on the surface of the thermistor element 11 described above. In the present embodiment, the protective film 15 may be formed by immersing the thermistor element 11 in a reaction solution including a silicon alkoxide, water, an organic solvent, and an alkali, and precipitating a silicon oxide (SiO₂) on the surface of the thermistor element 11 by a hydrolysis reaction and polycondensation reaction of the silicon alkoxide.

In order to carry out cutting to a predetermined chip size after the protective film 15 is formed, the protective film 15 is not formed on both end surfaces of the thermistor element 11 at this stage.

### (Base Electrode Layer Forming Step S03)

Next, the base electrode layer 21 is formed on both end portions of the thermistor element 11. The protective film 15 is not formed on both end surfaces of the thermistor element 11 and the base electrode layer 21 is formed to directly contact the thermistor element 11.

In the present embodiment, the base electrode layer 21 is formed by sintering a conductive paste including Ag powder and glass powder as the first conductive paste applied to both end portions of the thennistor element 11 and the base electrode layer 21 is formed of a sintered material of Ag.

### (Oxide Layer Forming Step S04)

Next, an oxide layer is formed on the surface of the base electrode layer 21. In the present embodiment, an oxide layer formed of a silicon oxide is formed by barrel sputtering.

Here, the thickness of the formed oxide layer is preferably in a range of 0.1 μm or more and 3 μm or less. The lower limit of the thickness of the oxide layer is preferably 0.2 μm or more, and more preferably 0.3 μm or more. On the other hand, the upper limit of the thickness of the oxide layer is preferably 2 μm or less, and more preferably 1.5 μm or less.

### (Cover Electrode Layer Forming Step S05)

Next, the cover electrode layer 22 is formed on the surface of the oxide layer described above.

In the present embodiment, the cover electrode layer 22 is formed by sintering a conductive paste including Ag powder and glass powder as the second conductive paste applied to the surface of the oxide layer and the cover electrode layer 22 is formed of a sintered material of Ag.

### (Conduction Heat Treatment Step S06)

Next, a heat treatment is carried out such that the base electrode layer 21 and the cover electrode layer 22 are electrically conductive. In this conduction heat treatment step S06, at least a part of the oxide layer disappears, such that the base electrode layer 21 and the cover electrode layer 22 are electrically conductive.

Here, in the conduction heat treatment step S06, it is necessary for the heating temperature to be the melting point or higher of both the glass frit in the base electrode layer 21 and the glass frit in the cover electrode layer 22. In other words, the optimum temperature changes depending on the glass frit used, but the temperature is preferably 50° C. or higher than the melting point of the glass frit in the cover electrode layer 22, and the temperature is more preferably 700° C. or higher from the viewpoint of sintering the Ag powder in the cover electrode layer 22. The upper limit of the heating temperature is preferably 900° C. or lower from the viewpoint of floating of the glass on the surface of the cover electrode layer 22. In addition, the melting point of the glass frit in the cover electrode layer 22 is preferably higher than the melting point of the glass frit in the base electrode layer 21.

The base electrode layer forming step S03, the oxide layer forming step S04, the cover electrode layer forming step S05, and the conduction heat treatment step S06 form the electrode portion 20 having a two-layer structure provided with the base electrode layer 21 and the cover electrode layer 22.

### (Plating Step S07)

Next, a metal plating layer is formed on the surface of the electrode portion 20. In the present embodiment, the Ni plating layer 31 is formed on the surface of the electrode portion 20 and then the Sn plating layer 32 is formed so as to be laminated on the Ni plating layer 31. In the present embodiment, the Ni plating layer 31 and Sn plating layer 32 described above are formed by wet barrel plating.

Here, when forming the Ni plating layer 31, the plating solution penetrates into the inside of the pores of the electrode portion 20. In the present embodiment, since the pores inside the base electrode layer 21 and the pores inside the cover electrode layer 22 do not communicate, the penetration of the plating solution is suppressed at the bonding interface between the base electrode layer 21 and the cover electrode layer 22.

Due to this, the penetration depth D of Ni of the Ni plating layer 31 into the electrode portion 20 is less than the thickness t of the electrode portion 20.

Through the above steps, the thermistor 10 of the present embodiment is manufactured.

According to the method for manufacturing the thermistor 10 of the present embodiment, which is configured as above, the electrode portion 20 is formed by the base electrode layer forming step S03, the oxide layer forming step S04, the cover electrode layer forming step S05, and the conduction heat treatment step S06, thus, the electrode portion 20 has a two-layer structure of the base electrode layer 21 and the cover electrode layer 22, the pores inside the base electrode layer 21 and the pores inside the cover electrode layer 22 do not communicate, and, in the subsequent plating step S07, the penetration of the plating solution is prevented at the interface between the cover electrode layer 22 and the base electrode layer 21 and it is possible to suppress contact between the thermistor element 11 and the plating solution. In addition, it is possible to suppress Ni precipitation at the interface between the thermistor element 11 and the electrode portion 20.

In addition, since the present embodiment is provided with the conduction heat treatment step S06 of performing a heat treatment such that the base electrode layer 21 and the cover electrode layer 22 are electrically conductive, even in a case where an oxide layer is formed between the base electrode layer 21 and the cover electrode layer 22, the base electrode layer 21 and the cover electrode layer 22 are electrically conductive and it is possible to secure the characteristics as the electrode portion 20.

In the conduction heat treatment step S06 of performing a heat treatment such that the base electrode layer 21 and the cover electrode layer 22 are electrically conductive, the glass frit included in one or both of the base electrode layer 21 and the cover electrode layer 22 and the oxide layer are reacted and eroded, such that the base electrode layer 21 and the cover electrode layer 22 become conductive. For this reason, it is necessary for the glass frit to be included in at least one of the base electrode layer 21 and the cover electrode layer 22 and being included in both is preferable.

Furthermore, in the present embodiment, in the base electrode layer forming step S03, the base electrode layer 21 is formed by sintering a glass-filled metal paste containing Ag powder and glass powder as the first conductive paste applied to the end surface of the thermistor element 11, thus, it is possible to improve the adhesion between the base electrode layer 21 and the thermistor element 11.

In addition, in the present embodiment, in the cover electrode layer forming step 505, since the cover electrode layer 22 is formed by sintering a glass-filled metal paste containing Ag powder and glass powder as the second conductive paste applied to the surface of the oxide layer, in the conduction heat treatment step S06, it is possible to efficiently eliminate at least a part of the oxide layer through a reaction between the glass and the oxide layer and to achieve sufficient conduction between the base electrode layer 21 and the cover electrode layer 22.

Furthermore, in the present embodiment, since the oxide formed between the base electrode layer 21 and the cover electrode layer 22 is formed of a silicon oxide, the oxide layer has excellent environmental resistance and it is possible to reliably form the cover electrode layer 22 on the surface of the oxide layer in the cover electrode layer forming step S05 and to stably form the electrode portion 20 having a two-layer structure of the base electrode layer 21 and the cover electrode layer 22.

Furthermore, in the thermistor 10 of the present embodiment, since the electrode portion 20 has a two-layer structure of the base electrode layer 21 and the cover electrode layer 22 and the penetration depth D of the Ni forming the Ni plating layer 31 into the electrode portion 20 is less than the thickness t of the electrode portion 20, contact between the plating solution and the thermistor element 11 in the plating step S07 is suppressed. In addition, Ni precipitation at the interface between the thermistor element 11 and the electrode portion 20 (the base electrode layer 21) is also suppressed. Thus, it is possible to provide the thermistor 10 having various stable characteristics.

Although one embodiment of the present invention was described above, the present invention is not limited thereto and appropriate changes are possible in a range not departing from the technical idea of the invention.

For example, in the present embodiment, a description was given in which the protective film is formed by immersing the thermistor element in a reaction solution; however, the protective film may be formed by other means without being limited thereto. For example, a protective film may be formed by applying and sintering a glass paste.

In addition, in the present embodiment, a description was given in which, after forming a protective film on a thermistor element, a base electrode layer is formed on the end surface of the thermistor element; however, without being limited thereto, after forming a base electrode layer on an end surface of a thermistor element, an oxide film may be formed on the entire surface of the thermistor element on which the base electrode layer is formed and the oxide layer and protective film may be formed at the same time. That is, the protective film forming step and the oxide layer forming step may be carried out at the same time.

Furthermore, in the present embodiment, a description was given in which the base electrode layer and the cover electrode layer are formed of a sintered material of Ag; however, without being limited thereto, for example, the above may be formed of a sintered material of an Ag alloy such as an Ag-Pd alloy, Au, Pt, Rh, Ir, or Ru oxides, or mixtures thereof. In addition, the base electrode layer and the cover electrode layer may be formed of different materials.

In addition, in the present embodiment, a description was given in which the oxide layer is formed of a silicon oxide; however, without being limited thereto, the above may be formed of other oxides such as alumina or titania.

### EXAMPLES

A description will be given of confirmation experiments performed to confirm the effectiveness of the present invention.

### Invention Example 1

On both surfaces of a thermistor wafer of 38×55 mm and 0.36 mm in thickness, a base electrode layer was formed by baking an Ag paste filled with glass frit printed on both surfaces of the wafer by screen printing. The thermistor wafer with the base electrode layer formed in this manner was attached to a dicing tape and cut to form 0.18 mm square chips by dicing using a diamond blade.

A 0.7 μm silicon oxide film (protective film and oxide layer) was formed by barrel sputtering on the thermistor chip prepared as described above.

A cover electrode layer was formed on the surface of the oxide layer with Ag paste by dipping and baking

Next, a conduction heat treatment was carried out under conditions of: atmosphere: air, heating temperature: 700° C., and holding time at heating temperature: 10 minutes.

Subsequently, a Ni plating layer was formed on the cover electrode layer by wet barrel plating and a Sn plating layer was further formed on the Ni plating layer.

### Invention Example 2

This Example was prepared in the same manner as in Invention Example 1, except that the film thickness of the silicon oxide film (protective film and oxide layer) was set to 0.1 μm and the cover electrode layer was formed of Au paste.

### Invention Example 3

This Example was prepared in the same manner as in Invention Example 1, except that the base electrode layer and the cover electrode layer were formed using a conductive paste containing metal powder formed of Ag-5 mass % Pd and the film thickness of the silicon oxide film (protective film and oxide layer) was 0.5 μm.

### Invention Example 4

On both surfaces of a thermistor wafer of 38×55 mm and 0.15 mm thickness, glass paste was printed by screen printing, baked, and then cut into strip shapes of 0.15 mm width by dicing using a diamond blade. Further, on both surfaces of the cut surface, glass paste was printed by screen printing, baked, and cut into chips with a width of 0.36 mm by dicing using a diamond blade.

A base electrode layer was formed on both end surfaces of the chip with Ag paste by dipping and baking

Subsequently, this Example was prepared in the same manner as in Invention Example 1, except that a silicon oxide film (protective film and oxide layer) with a film thickness of 3 μm was formed.

On both surfaces of a thermistor wafer of 38×55 mm and 0.36 mm in thickness, a RuO₂ intermediate layer was formed by spin-coating an ethanol dispersion solution with a RuO₂ concentration of 10 wt % with a raw material of RuO₂ powder manufactured by Kojundo Chemical Lab. Co., Ltd., using a paint shaker. Furthermore, a base electrode layer was formed by printing Ag paste filled with glass frit on both surfaces of the wafer by screen printing and carrying out baking under conditions of 800° C. for 10 minutes in air.

The thermistor wafer with the base electrode layer formed in this manner was attached to a dicing tape and cut to form 0.18 mm square chips by dicing using a diamond blade.

The thermistor chips prepared as described above were placed in a water-ethanol mixed solvent and ethyl orthosilicate and NaOH aqueous solution were added thereto while stirring to hydrolyze and polycondense the ethyl orthosilicate so as to form a 0.5 μm silicon oxide film (protective film and oxide layer).

Subsequently, the procedure was carried out in the same manner as in Invention Example 1.

### Invention Example 6

This Example was prepared in the same manner as in Invention Example 5, except that the base electrode layer was formed of Au paste and the film thickness of the silicon oxide film (protective film and oxide layer) was 1.0 μm.

### (Invention Example 7

This Example was prepared in the same manner as in Invention Example 5, except that the base electrode layer was formed of Pt paste and the film thickness of the silicon oxide film (protective film and oxide layer) was 1.2 μm.

### Comparative Example

This Example was prepared in the same manner as in Invention Example 4, except that the base electrode layer and the oxide layer were not formed.

The thermistors obtained as described above were evaluated for the following items.

### (Ni Penetration Depth D)

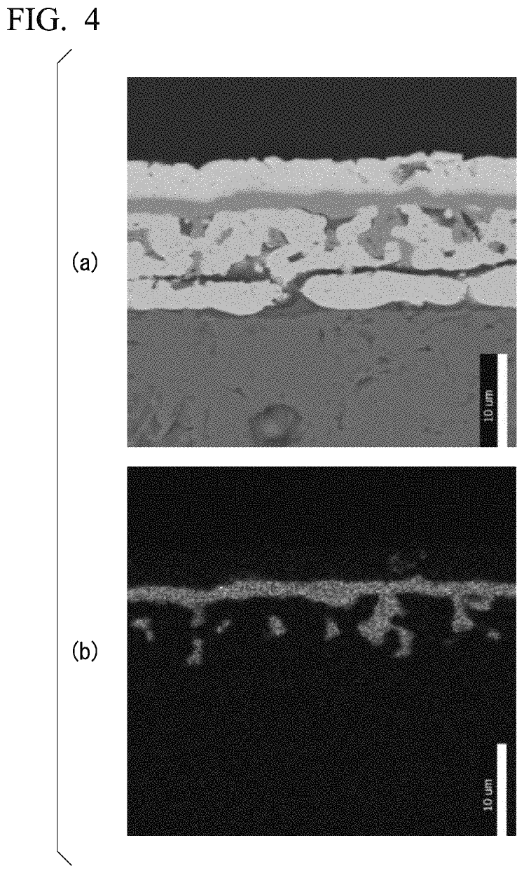

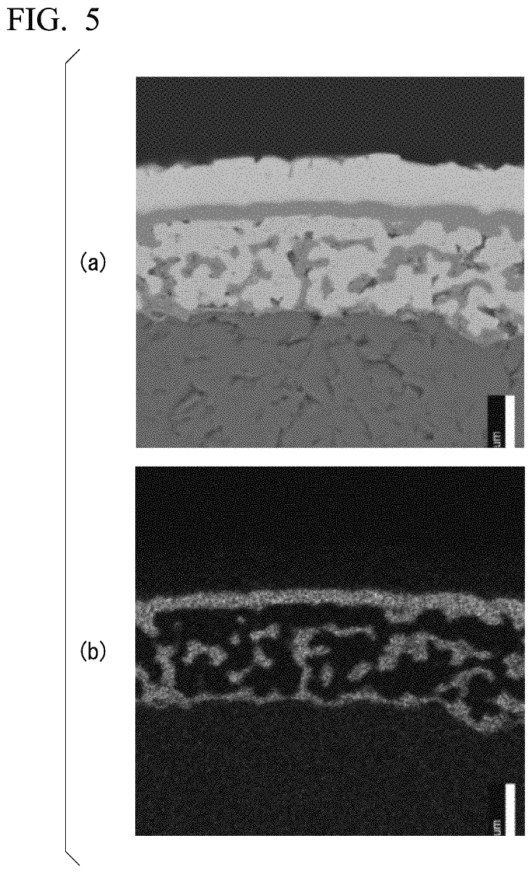

In addition, FIG. 4 shows the results of observing a cross-section of the electrode portion of Invention Example 1 and FIG. 5 shows the results of observing a cross-section of the electrode portion of the Comparative Example. In FIG. 4 and FIG. 5, (a) is an SEM image and (b) is an Ni mapping diagram.

The magnification was set such that the field of view encompassed from the thermistor element up to the electrode and an elemental mapping image was taken by SEM-EDS at 2500×. In this mapping image, the distance from the point where the components of the cover electrode layer were detected on the electrode surface side to the thermistor element was set as 1 and the maximum value of 1 in the field of view was set as I_{MAX}. Next, the distance from the point where the component of the plating layer was detected to the thermistor element was defined as d and the minimum value thereof was set as d_{MIN}. The value of I_{MAX}-d_{MIN} was set as the penetration depth D of the plating layer. lmAx was used as the thickness of the electrode portion.

### Electrical Characteristics

The distribution of resistance values (3 CV) at 25° C. was compared before and after plating. The elements before and after plating were put in a jig for measurement, the jigs were put in a waterproof bag and immersed in a constant temperature water bath adjusted to 25.00° C. for 15 minutes, and, after the temperature stabilized, the resistance values of twenty elements were measured using a digital multimeter. For the measured resistance values, the coefficient of variation CV, which was calculated by dividing the square root of the unbiased variance by the mean value, was multiplied by three to obtain 3 CV as a variation index.

TABLE 1

| | | | | | Cover electrode | | | | Ni | | Variations (3CV) | |
|---|---|---|---|---|---|---|---|---|---|---|---|---|
| | Base electrode layer | | Oxide layer | | layer | | | | penetration | | Before | After |
| | Material | Thickness | Material | Thickness | Material | Thickness | I_{MAX} | | depth D | | plating | plating |
| Invention | Ag | 3.2 μm | Silicon | 0.7 μm | Ag | 6.3 μm | 9.8 | μm | 6.5 | μm | 1.1% | 1.9% |
| example 1 | | | oxide | | | | | | | | | |
| Invention | Ag | 3.5 μm | Silicon | 0.1 μm | Au | 6.6 μm | 10.5 | μm | 7.1 | μm | 2.3% | 2.5% |
| example 2 | | | oxide | | | | | | | | | |
| Invention | Ag—Pd | 4.1 μm | Silicon | 0.5 μm | Ag—Pd | 5.8 μm | 11.0 | μm | 6.7 | μm | 1.8% | 1.7% |
| example 3 | | | oxide | | | | | | | | | |
| Invention | Ag | 6.2 μm | Silicon | 3.0 μm | Ag | 6.0 μm | 16.5 | μm | 14.0 | μm | 1.3% | 1.4% |
| example 4 | | | oxide | | | | | | | | | |
| Invention | RuO₂ + Ag | 4.1 μm | Silicon | 0.5 μm | Ag | 6.9 μm | 11.2 | μm | 7.2 | μm | 1.1% | 1.5% |
| example 5 | | | oxide | | | | | | | | | |
| Invention | Au | 4.6 μm | Silicon | 1.0 μm | Ag | 6.6 μm | 12.1 | μm | 7.9 | μm | 2.2% | 2.0% |
| example 6 | | | oxide | | | | | | | | | |
| Invention | Pt | 3.0 μm | Silicon | 1.2 μm | Ag | 6.7 μm | 11.5 | μm | 8.9 | μm | 1.3% | 1.2% |
| example 7 | | | oxide | | | | | | | | | |
| Comparative | — | — | — | — | Ag | 6.9 μm | 9.6 | μm | 9.6 | μm | 1.0% | 37.9% |
| example | | | | | | | | | | | | |

In the Comparative Example where the electrode portion was formed of one layer, as shown in FIG. 5, Ni penetrated to the bonding interface between the thermistor element and the electrode portion. For this reason, before and after plating, an increase in 3 CV of 9% or more was confirmed. It is assumed that this is due to contact between the thermistor element and the plating solution and deterioration of the thermistor element.

On the other hand, in the Invention Examples 1 to 7, in which the electrode portion had a two-layer structure and the Ni penetration depth D was less than the thickness of the electrode portion as shown in FIG. 4, the 3 CV did not change significantly before and after plating and the characteristics of the thermistor element were sufficiently stable.

As described above, according to the Invention Examples, it was confirmed that it is possible to provide a method for manufacturing a thermistor which manufactures a thermistor with which, even in a case where a plating layer is formed on a surface of an electrode portion, it is possible to suppress the penetration of a plating solution inside the electrode portion and in which a thermistor element has stable characteristics, as well as a thermistor having stable characteristics which is manufactured by this method for manufacturing a thermistor.

### REFERENCE SIGNS LIST

10: Thermistor

11: Thermistor element

15: Protective film

20: Electrode portion

21: Base electrode layer

1. A method for manufacturing a thermistor which includes a thermistor element and an electrode portion formed on an end surface of the thermistor element, the method comprising:
a base electrode layer forming step of forming a base electrode layer by applying and sintering a conductive paste on an end surface of the thermistor element;
an oxide layer forming step of forming an oxide layer on a surface of the base electrode layer;
a cover electrode layer forming step of forming a cover electrode layer by applying and sintering a conductive paste on a surface of the oxide layer; and
a conduction heat treatment step of performing a heat treatment such that the base electrode layer and the cover electrode layer are electrically conductive,
wherein the electrode portion having the base electrode layer and the cover electrode layer is formed and a plating step of forming a metal plating layer on a surface of the cover electrode layer is provided after the conduction heat treatment step.

2. The method for manufacturing a thermistor according to claim 1,
wherein the base electrode layer forming step forms the base electrode layer by applying and sintering a glass-filled metal paste containing metal powder and glass powder.

3. The method for manufacturing a thermistor according to claim 1,
wherein the cover electrode layer forming step forms the cover electrode layer by applying and sintering a glass-filled metal paste containing metal powder and glass powder.

4. The method for manufacturing a thermistor according to claim 1,
wherein the oxide layer is formed of a silicon oxide.

5. A thermistor comprising:
a thermistor element; and
an electrode portion formed on an end surface of the thermistor element,
wherein the electrode portion is provided with a base electrode layer formed on an end surface of the thermistor element and a cover electrode layer laminated on the base electrode layer, and a metal plating layer is formed on a surface of the electrode portion, and a penetration depth of a plating metal forming the metal plating layer into the electrode portion is less than a thickness of the electrode portion.

6. The method for manufacturing a thermistor according to claim 2,
wherein the cover electrode layer forming step forms the cover electrode layer by applying and sintering a glass-filled metal paste containing metal powder and glass powder.

7. The method for manufacturing a thermistor according to claim 2,
wherein the oxide layer is formed of a silicon oxide.

8. The method for manufacturing a thermistor according to claim 3,
wherein the oxide layer is formed of a silicon oxide.

9. The method for manufacturing a thermistor according to claim 6,
wherein the oxide layer is formed of a silicon oxide.
